(19) United States
(12) Patent Application Publication
(10) Pub. No.: US 2026/0157208 A1
(43) Pub. Date: Jun. 4, 2026

(54) PLATING APPARATUS AND PLATING METHOD

(71) Applicant: EBARA CORPORATION, Tokyo (JP)

(72) Inventors: Masashi SHIMOYAMA, Tokyo (JP); Yasuyuki MASUDA, Tokyo (JP); Ryosuke HIWATASHI, Tokyo (JP); Shingo YASUDA, Tokyo (JP); Masanori HAYASE, Tokyo (JP)

(21) Appl. No.: 18/717,268

(22) PCT Filed: Dec. 16, 2022
(86) PCT No.: PCT/JP2022/046409

§ 371 Date: Jun. 6, 2024

(51) Int. Cl. C25D 7/12; C25D 17/00; C25D 17/06; C25D 17/10; C25D 21/10; C25D 21/12

(52) U.S. Cl. CPC H10W 72/0112; C25D 5/022; C25D 5/18; C25D 5/22; C25D 7/123; C25D 17/001; C25D 17/008; C25D 21/10; C25D 21/12; H10W 72/01223; H10W 72/221

(57) ABSTRACT

Forming plural bumps on a substrate in such a manner that the bumps have uniform heights. A plating apparatus for forming bumps on a substrate is provide. The plating apparatus comprises: a substrate holder constructed to hold the substrate; a plating tank constructed to store plating liquid and the substrate holder; an anode arranged in the inside of the plating tank in such a manner that the anode faces the substrate held by the substrate holder; an electric power source constructed to supply electric current flowing between the substrate and the anode; and a controller; wherein the controller is constructed to make the electric power source output electric current that comprises a first period during that positive-direction electric current is supplied for depositing metal on the substrate from the plating liquid, a second period during that at lest one reverse-current pulse, that flows in a direction opposite to a direction of the positive-direction electric current, is supplied, and a third period during that supplying of electric current is stopped, wherein the third period is a period in the middle of a transition from the reverse-current pulse to the positive-direction electric current.

### TECHNICAL FIELD

The present invention relates to a plating apparatus and a plating method. Especially, the present invention relates to a plating apparatus and a plating method for forming a bump on a substrate.

### BACKGROUND ART

A process for forming a metal plated film, which comprises metal such as copper or the like, on a surface of a semiconductor device or a substrate for an electronic element has been practiced. For example, there is a case wherein a substrate, which is an object of plating, is held by a substrate holder, and the substrate, together with the substrate holder, is put in a plating tank storing plating liquid to soak it therein to electroplate it. The substrate holder holds the substrate in such a manner that a to-be-plated surface of the substrate is exposed. In the plating liquid, an anode is arranged to correspond to the exposed surface of the substrate and a voltage is applied between the substrate and the anode, so that an electroplated film can be formed on the exposed surface of the substrate.

For example, a photoresist layer having plural openings is arranged on a surface of a substrate. By applying a plating process to a substrate to which a photoresist layer such as that explained above has been added, bumps can be formed in the parts corresponding to the openings.

### CITATION LIST

### Patent Literature

PTL 1: Japanese Patent Application Public Disclosure No. 2006-131926
PTL2: Japanese Patent Application Public Disclosure No. 2011-026708

### SUMMARY OF INVENTION

### Technical Problem

It is required to form, on a substrate, plural bumps in such a manner that they have uniform height.

Patent Literature 1 discloses a technique to form a bump by performing a plating process during that a positive-current pulse and a negative-current pulse are applied alternatingly; however, Patent Literature 1 does not disclose any method for forming plural bumps having uniform height. Patent Literature 2 discloses a technique for forming a bump on a substrate by using a positive-voltage pulse and a reverse-voltage pulse. Further, a period of time during that the voltage is zero is set between the positive voltage and the negative voltage (FIGS. 16-18). However, since the voltage, instead of the electric current, is controlled, the electric current actually flowing through the plating liquid changes as time passes, i.e., as the plating film grows; accordingly, it is not possible to stably provide effect that is provided by the present invention and will be explained later (desorbing accelerator molecules, that will be explained with reference to FIG. 9). Further, since there may be a case wherein electric current flows through the plating liquid even if the applied voltage is zero, it is also not possible to sufficiently provide effect that is provided by the present invention and will be explained later (making density difference of accelerator molecules, that will be explained with reference to FIG. 9).

### Solution to Problem

According to an embodiment, a plating apparatus for forming bumps on a substrate is provided, and the plating apparatus comprises: a substrate holder constructed to hold the substrate; a plating tank constructed to store plating liquid and the substrate holder; an anode arranged in the inside of the plating tank in such a manner that the anode faces the substrate held by the substrate holder; an electric power source constructed to supply electric current flowing between the substrate and the anode; and a controller; wherein the controller is constructed to make the electric power source output electric current that comprises a first period during that positive-direction electric current is supplied for depositing metal on the substrate from the plating liquid, a second period during that at lest one reverse-current pulse, that flows in a direction opposite to a direction of the positive-direction electric current, is supplied, and a third period during that supplying of electric current is stopped, wherein the third period is a period in the middle of a transition from the reverse-current pulse to the positive-direction electric current.

Further, according to an embodiment, a method for forming bumps on a substrate is provided, and the method comprises: supplying, between the substrate and an anode arranged in a plating tank, electric current that comprises a first period during that positive-direction electric current is supplied for depositing metal on the substrate from a plating liquid in the plating tank, a second period during that at lest one reverse-current pulse, that flows in a direction opposite to a direction of the positive-direction electric current, is supplied, and a third period during that supplying of electric current is stopped, wherein the third period is a period in the middle of a transition from the reverse-current pulse to the positive-direction electric current.

### BRIEF DESCRIPTION OF DRAWINGS

FIG. 1 is a general layout drawing of a plating apparatus according to an embodiment of the present invention.

FIG. 2 is a schematic cross-sectional side view of a plating module according to an embodiment of the present invention.

FIG. 3 is a schematic diagram which shows a bump formed by using a plating apparatus according to an embodiment of the present invention.

FIG. 4 is a graph which shows a time waveform of plating electric current outputted from an electric power source in a plating apparatus according to an embodiment of the present invention.

FIG. 5 is a graph which shows a time waveform of plating electric current that is different from the time waveform shown in FIG. 4.

FIG. 6 is a schematic diagram which shows an opening pattern on a photoresist layer used for forming plural bumps.

FIG. 7 shows measurement examples of bump heights, BHs, in the case that plural bumps are formed by using the photoresist layer shown in FIG. 6.

FIG. 8 is a graph which shows degrees of dispersion of the bump heights, ΔBHs, in the case that the condition of the plating electric current is changed variously and the bumps are formed under the respective conditions, wherein the respective degrees of dispersion correspond to the respective conditions.

FIG. 9 is a conceptual drawing for explaining a principle that improves uniformity of height of plural bumps.

FIG. 10 is a graph which is used to compare the cases when stirring of the plating liquid is stopped and is not stopped in a second period T2.

FIG. 11 is a graph which shows a time waveform of plating electric current outputted from an electric power source in a plating apparatus according to an embodiment of the present invention.

### DESCRIPTION OF EMBODIMENTS

In the following description, embodiments of the present invention will be explained with reference to the figures. In the figures which will be explained below, a reference symbol that is the same as that assigned to one component is assigned to the other component which is the same as or corresponds to the one component, and overlapping explanation of these components will be omitted.

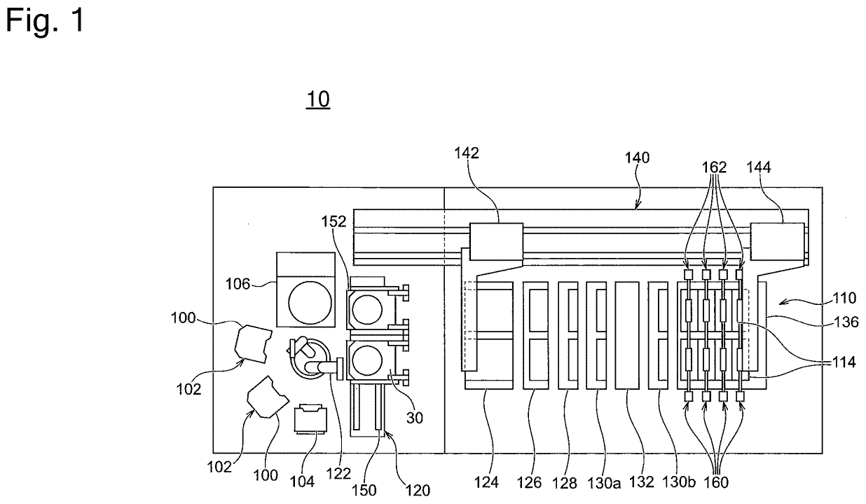

FIG. 1 is a general layout drawing of a plating apparatus 10 according to an embodiment of the present invention. As shown in FIG. 1, the plating apparatus 10 comprises: two cassette tables 102; an aligner 104 for aligning, in a predetermined direction, a position of an orientation flat, a notch, or the like of a substrate; and a spin rinse dryer 106 for drying, after completion of a plating process of a substrate, the substrate by rotating it at high speed. A cassette 100, in which a substrate such as a semiconductor wafer or the like is housed, is loaded onto the cassette table 102. A load/unload station 120, onto which a substrate holder 30 is loaded to attach/detach a substrate thereto/therefrom, is installed in a position close to the spin rinse dryer 106. In a position in the center of the above units 100, 104, 106, and 120, a transfer robot 122 which carries a substrate between the above units is arranged.

The load/unload station 120 comprises loading plates 152, wherein each loading plate 152 has a flat plate shape and is able to slide in a lateral direction along rails 150. Two substrate holders 30 are loaded, in parallel with each other in a horizontal state, onto the loading plates 152; and, after completion of delivery of a substrate between one of the substrate holders 30 and the transfer robot 122, the loading plates 152 are slid in a lateral direction, and delivery of a substrate between the other of the substrate holders 30 and the transfer robot 122 is performed.

The plating apparatus 10 further comprises a stocker 124, a pre-wet module 126, a pre-soak module 128, a first rinse module 130a, a blow module 132, a second rinse module 130b, and a plating module 110. In the stocker 124, storing and temporary storing of a substrate holder 30 is performed. In the pre-wet module 126, a substrate is soaked in pure water. In the pre-soak module 128, an oxide film on a surface of an electrically conducting layer such as a seed layer or the like formed on a surface of a substrate is removed by etching. In the first rinse module 130a, a substrate is rinsed together with a substrate holder 30 by using a cleaning solution (pure water or the like) after pre-soaking. In the blow module 132, liquid removal of a substrate is performed after rinsing. In the second rinse module 130b, a plated substrate is rinsed together with a substrate holder 30 by using a cleaning solution. The load/unload station 120, the stocker 124, the pre-wet module 126, the pre-soak module 128, the first rinse module 130a, the blow module 132, the second rinse module 130b, and the plating module 110 are arranged in the above listed order.

For example, the plating module 110 is constructed in such a manner that plural plating tanks 114 are housed in the inside of an overflow tank 136. In the example of FIG. 1, the plating module 110 comprises eight plating tanks 114. Each plating tank 114 is constructed in such a manner that it receives a single substrate in the inside thereof, soaks the substrate in plating liquid held in the inside thereof, and applies plating such as copper plating or the like to a surface of the substrate.

The plating apparatus 10 comprises a transfer apparatus 140 which is arranged in a position on a side of the above respective devices, adopts, for example, a linear motor system, and conveys a substrate holder 30, together with a substrate, between the above respective devices. The transfer apparatus 140 comprises a first transfer apparatus 142 and a second transfer apparatus 144. The first transfer apparatus 142 is constructed to convey a substrate between the load/unload station 120, the stocker 124, the pre-wet module 126, the pre-soak module 128, the first rinse module 130a, and the blow module 132. The second transfer apparatus 144 is constructed to convey a substrate between the first rinse module 130a, the second rinse module 130b, the blow module 132, and the plating module 110. The plating apparatus 10 may be constructed in such a manner that it does not comprise the second transfer apparatus 144, i.e., it comprises the first transfer apparatus 142 only.

In positions on both sides of the overflow tank 136, paddle drivers 160 and paddle followers 162 are arranged, wherein each of the paddle drivers 160 and each of the paddle followers 162 drive a paddle which is arranged in each of the plating tanks 114 and works as a stirring rod for stirring plating liquid in the plating tank 114.

An example of a series of plating processes performed by the plating apparatus 10 will be explained. First, a substrate is taken out by the transfer robot 122 from the cassette 100 loaded on the cassette table 102, and the substrate is conveyed to the aligner 104. The aligner 104 aligns, in a predetermined direction, a position of an orientation flat, a notch, or the like. The substrate, which has been aligned with respect to the direction by the aligner 104, is conveyed by the transfer robot 122 to the load/unload station 120.

Regarding the load/unload station 120, two substrate holders 30, which have been stored in the stocker 124, are gripped at the same time by the first transfer apparatus 142 in the transfer apparatus 140, and conveyed to the load/unload station 120. Thereafter, the two substrate holders 30 are put, at the same time and horizontally, on the loading plates 152 in the load/unload station 120. In the above state, the transfer robot 122 conveys the substrates to the substrate holders 30, respectively, and the conveyed substrates are held in the substrate holders 30, respectively.

Next, the two substrate holders 30, which hold the substrates, are gripped at the same time by the first transfer apparatus 142 in the transfer apparatus 140, and housed in the pre-wet module 126. Next, the substrate holders 30, which hold the substrates processed in the pre-wet module 126, are conveyed to the pre-soak module 128 by the first transfer apparatus 142, and, in the pre-soak module 128, an etching process is applied to an oxide film on each of the substrates. Following thereto, the substrate holders 30, which hold the above substrates, are conveyed to the first rinse module 130a, and the surfaces of the substrates are rinsed by pure water stored in the first rinse module 130a.

The substrate holders 30, which hold the substrates with respect to which the rinsing process applied thereto has been completed, are conveyed from the first rinse module 130a to the plating module 110 by the second transfer apparatus 144, and housed in the plating tanks 114 which have been filled with plating liquid. The second transfer apparatus 144 repeats the above procedures sequentially to thereby sequentially house the substrate holders 30, which hold substrates, in the plating tanks 114 in the plating module 110, respectively.

In each of the plating tanks 114, a surface of the substrate is plated by supplying plating electric current between the substrate and an anode (not shown in the figure) in the plating tank 114, and, at the same time, moving the paddle forward and backward, in parallel with the surface of the substrate, by the paddle driver 160 and the paddle follower 162.

After completion of plating, two substrate holders 30, which hold the plated substrates, are gripped at the same time by the second transfer apparatus 144, and conveyed to the second rinse module 130b, and the surfaces of the substrates are rinsed by pure water by soaking them in the pure water stored in the second rinse module 130b. Next, the substrate holders 30 are conveyed to the blow module 132 by the second transfer apparatus 144, and water droplets remaining on the substrate holders 30 are removed by air-blowing or the like. Thereafter, the substrate holders 30 are conveyed to the load/unload station 120 by the first transfer apparatus 142.

In the load/unload station 120, the processed substrate is taken out from the substrate holder 30 by the transfer robot 122, and conveyed to the spin rinse dryer 106. The spin rinse dryer 106 rotates, at high speed, the plated substrate to thereby dry it. The dried substrate is returned to the cassette 100 by the transfer robot 122.

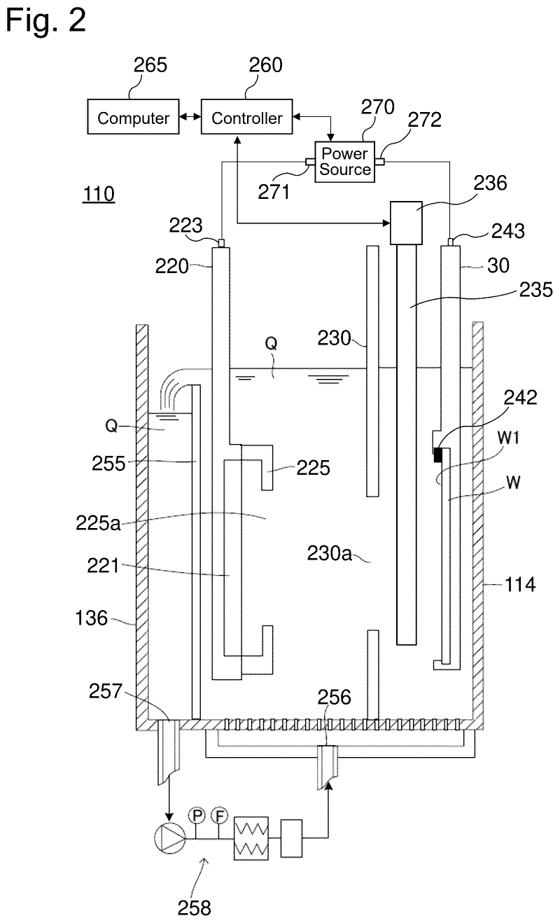

FIG. 2 is a schematic cross-sectional side view of the above-explained plating module 110. As shown in the figure, the plating module 110 comprises an anode holder 220 which is constructed to hold an anode 221, the substrate holder 30 which is constructed to hold a substrate W, the plating tank 114 which stores plating liquid Q including an additive, and the overflow tank 136 which receives and discharges a quantity of plating liquid Q overflowed from the plating tank 114. The plating tank 114 and the overflow tank 136 are separated from each other by a partition wall 255. The anode holder 220 and the substrate holder 30 are housed in the inside of the plating tank 114. As explained above, the substrate holder 30 holding the substrate W is conveyed by the second transfer device 144 (refer to FIG. 1) and housed in the plating tank 114.

In this regard, although a single plating tank 114 only is drawn in FIG. 2, the plating module 110 may be that comprising plural plating tanks 114 as explained above, wherein each plating tank may be that comprising the construction shown in FIG. 2.

The anode 221 is electrically connected to a positive terminal 271 of an electric power source 270 via an electric terminal 223 installed on the anode holder 220. The substrate W is electrically connected to a negative terminal 272 of the electric power source 270, via an electric contact 242 which is in contact with a periphery of the substrate W and an electric terminal 243 installed on the substrate holder 30. The electric power source 270 is constructed in such a manner that it supplies plating electric current between the anode 221 connected to the positive terminal 271 and the substrate W connected to the negative terminal 272, and also measures an applied voltage between the positive terminal 271 and the negative terminal 272.

Further, the electric power source 270 is connected to a controller 260 which controls operation of the electric power source 270, and the controller 260 is connected to a computer 265. The computer 265 provides a user interface for an operator of the plating apparatus 10. The operator of the plating apparatus 10 can input, via the computer 265, various kinds of setting information relating to plating processes. For example, the setting information includes a set value of plating electric current outputted from the electric power source 270. The controller 260 makes the electric power source 270 operate in accordance with a plating-electric-current set value inputted by the operator. Further, the controller 260 provides the computer 256 with status information that is based on information of a voltage that is applied between the terminals 271 and 272 and measured by the electric power source 270. The operator of the plating apparatus 10 can receive the status information via the computer 265. The controller 260 may be constructed in such a manner that it controls operation of respective parts other than the electric power source 270 in the plating module 110, or respective units other than the plating module 110 in the plating apparatus 10, and provides the computer 265 with various kinds of status information relating to above operation.

The anode holder 220 holding the anode 221 and the substrate holder 30 holding the substrate W are soaked in the plating liquid Q in the plating tank 114, and arranged to face with each other in such a manner that the anode 220 and the to-be-plated surface W1 of the substrate W are positioned in virtually parallel with each other. In the state that the anode 221 and the substrate W are being soaked in the plating liquid Q in the plating tank 114, the plating electric current is supplied from the electric power source 270 to them. As a result, metal ions in the plating liquid Q are deoxidized on the to-be-plated surface W1 of the substrate W, and a film is formed on the to-be-plated surface W1.

The anode holder 220 comprises an anode mask 225 for adjusting an electric field between the anode 221 and the substrate W. The anode mask 225 is a member which is virtually tabular and comprises dielectric material, for example, and installed in a position on a front surface side of the anode holder 220 (a surface on a side facing the substrate holder 30). That is, the anode mask 225 is positioned between the anode 221 and the substrate holder 30. The anode mask 225 comprises a first opening 225a, through which the electric current flowing between the anode 221 and the substrate W passes. It is preferable that the diameter of the opening 225a be smaller than the diameter of the anode 221. The anode mask 225 may be constructed in such a manner that the diameter of the opening 225a is adjustable.

The plating module 110 further comprises a regulation plate 230 for adjusting the electric field between the anode 221 and the substrate W. The regulation plate 230 is a member which is virtually tabular and comprises dielectric material, for example, and arranged in a position between the anode mask 225 and the substrate holder 30 (the substrate W). The regulation plate 230 comprises a second opening 230a, through which the electric current flowing between the anode 221 and the substrate W passes. It is preferable that the diameter of the opening 230a be smaller than the diameter of the substrate W. The regulation plate 230 may be constructed in such a manner that the diameter of the opening 230a is adjustable.

A paddle 235 is arranged in a position between the regulation plate 230 and the substrate holder 30, for stirring the plating liquid Q held in a region near the to-be-plated surface W1 of the substrate W. The paddle 235 is a member having a virtually rod shape, and arranged in the plating tank 114 in such a manner that it extends in a vertical direction.

One of ends of the paddle 235 is fixed to the paddle driving device 236. Operation of the paddle driving device 236 is controlled by the controller 260, and the paddle 235 is moved horizontally by the paddle driving device 236 in a direction along the to-be-plated surface W1 of the substrate W. The plating liquid Q is stirred thereby.

The plating tank 114 comprises a plating liquid supply port 256 for supplying the plating liquid Q to the inside of the tank. The overflow tank 136 comprises a plating liquid exhaust port 257 for discharging a quantity of plating liquid Q overflowed from the plating tank 114. The plating liquid supply port 256 is arranged in a position on the bottom of the plating tank 114, and the plating liquid exhaust port 257 is arranged in a position on the bottom of the overflow tank 136.

When the plating liquid Q is being supplied from the plating liquid supply port 256 to the plating tank 114, a quantity of plating liquid Q overflows from the plating tank 114, and flows into the overflow tank 136 over the partition wall 255. The plating liquid Q flown into the overflow tank 136 is discharged from the plating liquid exhaust port 257, and impurities therein are removed by a filter or the like included in a plating liquid circulating device 258. The plating liquid Q, from which the impurities have been removed, is supplied to the plating tank 114 by the plating liquid circulating device 258 via the plating liquid supply port 256.

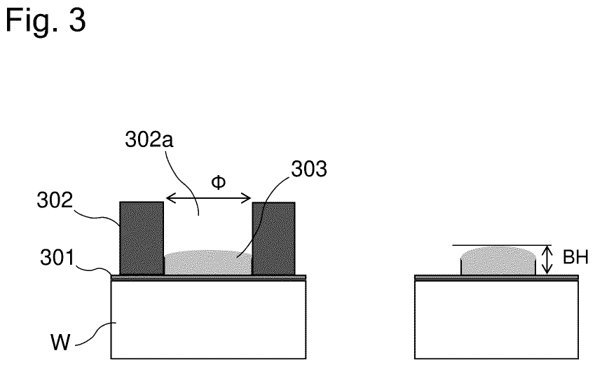

FIG. 3 is a schematic diagram which shows a bump formed on the substrate W by applying a plating process on a surface of the substrate W, by using the plating apparatus 10 according to an embodiment of the present invention. A metal thin seed layer 301 has been formed on the whole surface of the substrate W in advance, and, during the plating process, electric power is supplied to the surface of the substrate W via the seed layer 301. A photoresist layer 302 is formed on the seed layer 301, and the photoresist layer 302 comprises an opening 302a where a bump is to be formed. The substrate W, on which the photoresist layer 302 has been formed as explained above, is held by the substrate holder 30, and soaked in the plating liquid Q in the plating tank 114 for plating it. During the plating process, the part other than that of the opening 302a in the photoresist layer 302 on the surface of the substrate W is shielded by the photoresist layer 302. Thus, a plating film grows only on a bottom surface of the opening 302a in the photoresist layer 302, and, accordingly, a bump 303 is formed on the substrate W. In this regard, the photoresist layer 302 is removed after completion of the plating process (refer to the right-side half in FIG. 3).

Plural bumps 303, each of which are similar to the bump explained above, are formed on the substrate W by using a photoresist layer 302 having a predetermined opening pattern. Even in the same substrate W, there may be dispersion in height (film thickness) of the bumps 303 respectively formed in the openings, according to the sizes of the openings (i.e., the opening diameters) and the density of openings (i.e., the number of openings per unit area). Thus, it is required to form plural bumps 303 on the substrate W in such a manner that the height of each bump 303 becomes identical with those of other bumps 303.

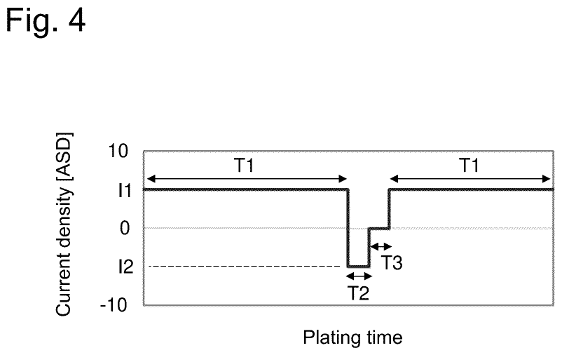

FIG. 4 is a graph which shows a time waveform of plating electric current, that is outputted from an electric power source 270 and flows between the anode 221 and the substrate W, in the plating apparatus 10 according to an embodiment of the present invention. As shown in FIG. 4, the electric power source 270 outputs positive-direction current in a first period T1. The term “positive direction” refers to the direction of the electric current flowing from the anode 221 to the substrate W through the plating liquid Q. Thus, in the first period T1, metal ions in the plating liquid Q are reduced on the to-be-plated surface W1 of the substrate W, and, accordingly, metal is deposited on the to-be-plated surface W1 (i.e., a plating film is formed). The length of the first period T1 may be the length of time corresponding to a large fraction of the whole length of time of the plating process, for allowing substantial growth of the plating film. In other words, the sum of the length of the second period T2 and the length of the third period T3, that will be explained later, may be set to a length of time that can be ignored when it is compared with the length of the first period T1. The magnitude of the positive-direction current may be set to a constant electric current value I1 through the whole of the first period T1. In a different construction, the electric current value I1 of the positive-direction current may be controlled to be changed over time.

In the second period T2 inserted in the middle of the first period T1, the electric power source 270 outputs electric current in a direction opposite to that of the above-explained positive-direction electric current. During the second period T2, the electric current keeps an electric current value 12 that has a sign different from that of I1. The length of the second period T2 is very short when it is compared with the length of the first period T1. Accordingly, the electric current in the second period T2 has a pulse shape, and, in the following description in the present specification, the above electric current will be referred to as a “reverse-current pulse.” For example, the length of the second period T2, i.e., the pulse width of the reverse-current pulse, may be set to that in a range approximately between 0.1 second to several seconds. In the second period T2, opposite to the case of the reduction reaction of metal ions in the first period T1, the metal in some parts of the plating film that has been formed during the first period T1 on the to-be-plated surface W1 is dissolved again in the plating liquid Q, and, at the same time, the accelerator (one of additives included in the plating liquid Q) adhered to the outermost surface of the plating film during the reduction reaction is desorbed from the surface of the plating film. Details relating to the above matters will be explained later.

In this regard, it is preferable that the electric current value I2 of the reverse-current pulse be set to a value that makes it possible to sufficiently desorb the accelerator. Further, in the case that the electric current value I2 is set to be equal to the electric current value I1, a combination comprising an electric power source which outputs single-polarity electric current and a polarity inversion switch that can invert the output of the electric power source may be used, instead of using the electric power source 270 which outputs both positive-polarity electric current and negative-polarity electric current as explained above.

Further, in the third period T3 that follows the second period T2, the electric power source 270 stops outputting of the electric current. That is, in the third period T3, the electric current does not flow in neither the positive direction nor the reverse direction in the plating liquid Q. Similar to the case of the second period T2, the length of the second period T3 is very short when it is compared with the length of the first period T1, and it may be set to that in a range approximately between 0.1 second to several seconds. In this regard, although details will be explained later, the diffusion of the accelerator desorbed from the surface of the plating film progresses in the plating liquid Q in the third period T3.

After the end of the third period T3, the electric power source 270 again outputs the positive-direction electric current (electric current value I1). Outputting of the positive-direction electric current is continued until the end of predetermined processing time, for example, until the film thickness of the formed plating film reaches a predetermined target film thickness.

In the manner explained above, in the embodiment shown in FIG. 4, the electric power source 270 supplies a single reverse-current pulse in the middle of the first period T1 during that the positive-direction electric current is supplied, and stops supplying of electric current during a short period of time that immediately follows the reverse-current pulse. The temporal position of the reverse-current pulse (and the electric current stopping period following thereto) in the whole of the first period T1 is not specifically limited; however, in view of uniformizing of the height of the plural bumps 303 formed on the substrate W, it is preferable that the reverse-current pulse be started at timing in the first half period of the whole period of the plating process (the reason will be explained later).

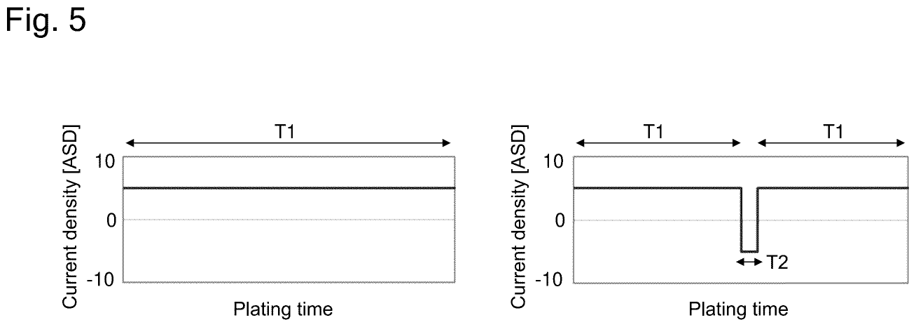

FIG. 5 is a graph which shows a time waveform of plating electric current that is different from the time waveform shown in FIG. 4. The graph in the left-side half of FIG. 5 shows the case that the positive-direction electric current is continuously supplied during the whole period (the period T1) of the plating process. The graph in the right-side half of FIG. 5 shows the case that a single reverse-current pulse (the period T2) is supplied in the middle of the plating process period T1, without performing operation to stop electric current.

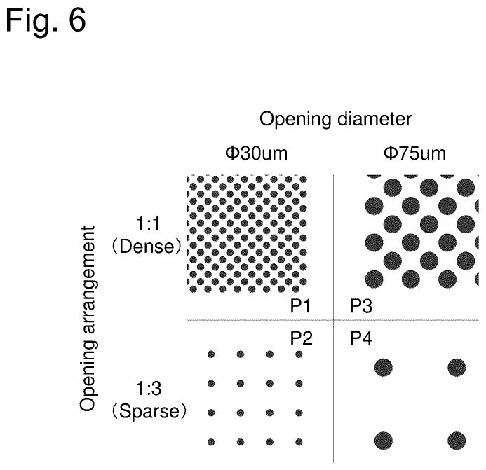

Next, result of an experiment relating to uniformity of the height of the plural bumps 303 formed on the substrate W will be explained. FIG. 6 is a schematic diagram which shows an opening pattern on the photoresist layer 302 used for forming plural bumps 303 in the present experiment. In the opening pattern shown in FIG. 6, openings 302a, each having a small opening diameter o (refer to FIG. 3), are arranged densely in a pattern region P1; openings 302a, each having the small opening diameter o, are arranged sparsely (non-densely) in a pattern region P2; openings 302a, each having a large opening diameter o, are arranged densely in a pattern region P3; and openings 302a, each having the large opening diameter q, are arranged sparsely in a pattern region P4.

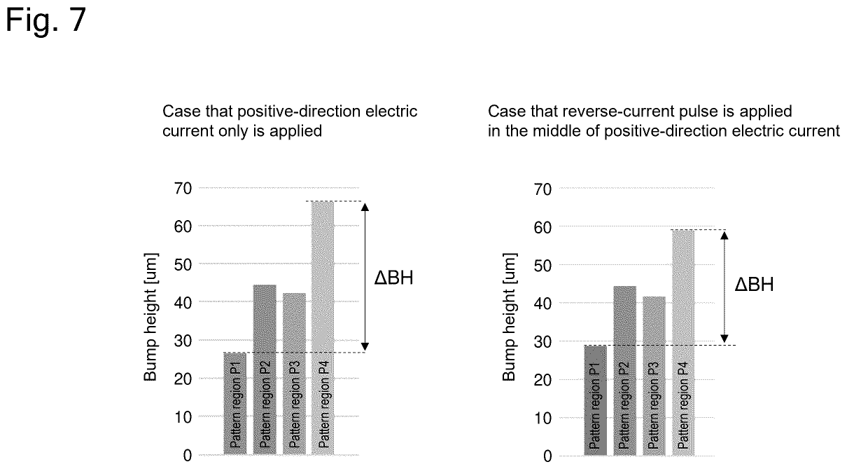

FIG. 7 is a graph that shows measurement examples of the bump heights, BHs (refer to FIG. 3), of the bumps 303 in the respective pattern regions, in the case that the plural bumps 303 are formed on the substrate W by using the photoresist layer 302 shown in FIG. 6. In FIG. 7, the bump height BH corresponding to each one of the pattern regions P1, P2, P3, and P4 represents the value obtained by measuring heights of plural bumps 303 included in the pattern region and calculating an average of the measured heights. The graph in the left-side half of FIG. 7 shows measurement results in the case that the bumps 303 were formed by supplying the positive-direction electric current throughout the whole plating process period as shown in the graph in the left-side half of FIG. 5; and the graph in the right-side half of FIG. 7 shows measurement results in the case that the bumps 303 were formed by supplying a single reverse-current pulse in the middle of the plating process period as shown in the graph in the right-side half of FIG. 5.

As shown in FIG. 7, the respective heights BHs of the bumps 303 formed on the respective patter regions in the substrate W are different from one another although the bumps were formed on the same substrate; and it can be observed that, among the heights relating to the respective pattern regions, the bump height BH relating to the pattern region Pl is the lowest and the bump height BH relating to the pattern region P4 is the highest.

The reason is that, as the diameter o of the opening 302 becomes smaller and/or the density of arrangement of the openings 302a becomes higher, it becomes more difficult to sufficiently supply metal ions to the inside of each opening 302, and, as a result, the plating film forming rate becomes lower. In the present example, as shown in FIG. 7, the difference between the maximum value and the minimum value of the heights BHs in the substrate is defined as bump height dispersion ΔBH. It can be understood from FIG. 7 that the degree of the bump height dispersion ΔBH in the case that a reverse-current pulse is supplied in the middle of the plating process period (the graph in the right-side half of FIG. 7) is smaller than that in the case that a reverse-current pulse is not supplied (the graph in the left-side half of FIG. 7).

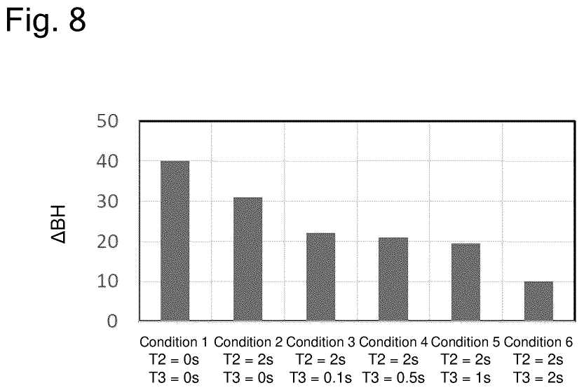

FIG. 8 is a graph which shows degrees of the bump height dispersion ΔBHs, in the case that the condition of the plating electric current is changed variously and the bumps are formed under the respective changed conditions, wherein the respective degrees of the bump height dispersion correspond to the respective conditions. Plating electric current under a condition 1 corresponds to the plating electric current shown in the graph in the left-side half of FIG. 5 (i.e., the case wherein the positive-direction electric current is supplied throughout the whole plating process period), and plating electric current under a condition 2 corresponds to the plating electric current shown in the graph in the right-side half of FIG. 5 (i.e., the case wherein the positive-direction electric current and the single reverse-current pulse are supplied during the plating process period). The degrees of the bump height dispersion ΔBHs relating to the above two conditions are the same as the degrees of the bump height dispersion ΔBHs that have already been shown in the graph in FIG. 7.

In FIG. 8, each of plating electric currents under corresponding one of conditions 3-6 corresponds to the plating electric current shown in FIG. 4. That is, under each of the conditions 3-6, the bumps 303 are formed by performing, in the middle of the period for supplying positive-direction electric current, operation for supplying a single reverse-current pulse and stopping the electric current for a short period of time right after the end of the single reverse-current pulse. As shown in FIG. 8, the degree of bump height dispersion ΔBH can be lowered further by forming the bumps 303 by using electric current such as that explained above; specifically, it can be lowered than that measured in the state that the plating electric current under the condition 2 is used. That is, it becomes possible to form, on the substrate W, plural bumps 303 to have more uniform height, even in the case that the plural bumps 303 having different diameters are to be formed and/or in the case that areas having different degrees of density of arrangement of the plural bumps 303 are to be included in the substrate W.

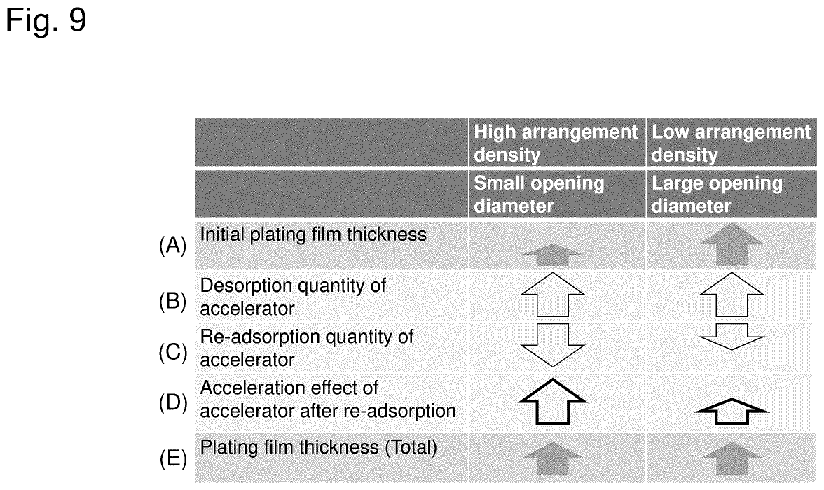

FIG. 9 is a conceptual drawing for explaining a principle that improves, by using the plating electric current shown in FIG. 4, uniformity of the height of plural bumps 303. As explained above, on the to-be-plated surface W1 of the substrate W, the plating film forming rate in an area, wherein the diameter of the opening 302a in the photoresist layer 302 is large, and the plating film forming rate in an area, wherein the density of arrangement of the openings 302 in the photoresist layer 302 is low (for example, the pattern region P4 in FIG. 6), are higher than that in an area (for example, the pattern region P1) different from the above two kinds of areas. Thus, in the period before the second period T2, during that the reverse-current pulse is supplied, in the first period T1 during that the positive-direction electric current is supplied, the plating film thickness in an area wherein the diameter is large and/or the arrangement density is low becomes larger than the plating film thickness in an area wherein the diameter is small and/or the arrangement density is high (the stage (A) in FIG. 9).

On the other hand, the plating liquid Q includes, as one of additives, an accelerator (for example, SPS (Bis-(3-sulphopropyl)-disulphide) or the like) that provides effect to facilitate growing of a plating film. Irrespective of positions on a surface of a plating film, molecules of an accelerator such as that explained above are condensed and have certain density, and adsorbed on the surface to facilitate the reduction reaction of metal ions. In the second period T2 during that a reverse-current pulse is supplied, the accelerator molecules are desorbed from the surface of the plating film, and diffused in the inside of the opening 302 and areas close thereto. At that time, since the accelerator molecules are originally condensed and have certain density, and adsorbed on the surface of the plating film, the local density, in the inside of each opening 302a, of the accelerator molecules desorbed from the surface of the plating film remains constant (the stage (B) in FIG. 9).

However, in an area wherein the density of openings is high, desorbed accelerator molecules exist in neighboring openings 302a in a manner similar to that explained above; accordingly, the concentration gradient relating to the accelerator molecules in an area close to the above plural openings 302a is small. Thus, the number of accelerator molecules, in the above accelerator molecules, which diffuse into areas distant from the openings 302a is small, and many of the accelerator molecules stay in areas close to the openings 302a. On the other hand, in an area wherein the density of openings is low, effect relating to the neighboring openings 302a is small; accordingly, the concentration gradient relating to the accelerator molecules in an area close to the plural openings 302a is large. Thus, many of the accelerator molecules, that have been desorbed from the plating film, diffuse into distant areas, and a small number of the accelerator molecules remain in areas close to the openings 302a. As a result, during the third period T3 during that no electric current flows in the plating liquid Q, the average concentration of the accelerator molecules becomes high in an area close to the openings 302a which are arranged in an area wherein the density of openings is high, compared with the average concentration of the accelerator molecules in an area close to the openings 302a which are arranged in an area wherein the density of openings is low. That is, the average concentration of the accelerator molecules changes according to the degree of the density of openings. Further, difference in the sizes of the openings 302a also results in difference in the degrees of concentration of the accelerator molecules similarly (the accelerator molecules are prone to diffuse into the outside of an opening 302a if the opening diameter thereof is large, so that the concentration of the accelerator molecules becomes low in an area close to an opening 302a having a large opening diameter).

As explained above, the concentration of the accelerator molecules in an area close to an opening 302a changes according to the construction (i.e., the diameter and the arrangement density) of the opening 302a in which a plating film is to be formed; thus, when supplying of the positive-direction electric current is resumed after the end of the third period T3, the quantities of accelerator molecules that are to be adsorbed to parts of the surface of the plating film in the openings 302a become different from one another according to areas. Specifically, the quantity of accelerator molecules, that are to be adsorbed again, is relatively low in an area wherein the diameters of the openings are large and/or the density of the openings is low, and the quantity of accelerator molecules, that are to be adsorbed again, is relatively high in an area wherein the diameters of the openings are small and/or the density of the openings is high (the stage (C) in FIG. 9).

Further, since desorption of the accelerator occurs generally as explained above (the stage (B)), the density (or the quantity) of the accelerator molecules, which are adsorbed again and accordingly exist on the surface of the plating film, becomes relatively small in an opening 302a which has been arranged in an area wherein the diameters of the openings are large and/or the density of the openings is low, and becomes relatively large in an opening 302a which has been arranged in an area wherein the diameters of the openings are small and/or the density of the openings is high, when the whole of the process from desorption to re-adsorption is taken into consideration (the stage (D) in FIG. 9). Thus, effect of the accelerator becomes high and the plating rate increases accordingly on the surface of the plating film in the case that the position of the surface of the plating film is that in an area wherein the diameters of the openings are small and/or the density of the openings is high, compared with that in the case that the position of the surface of the plating film is that in an area wherein the diameters of the openings are large and/or the density of the openings is low. By taking the above matters into consideration, difference in film thickness, that has originally been observed and relates to positions of areas in the plating film (refer to the stage (A)), can be compensated, and, as a result, the film thickness of the plating film (i.e., the bumps 303) formed in the openings 302a can be uniformized irrespective of difference in constructions of the openings 302a (the stage (E) in FIG. 9).

As can be understood from the above explanation, for uniformizing the height of the bumps 303, it is important to make difference in degrees of density of the accelerator molecules, which are to be re-adsorbed after desorption thereof, according to areas. Further, as explained above, the density difference is produced due to the matter that the degrees of diffusing of the desorbed accelerator molecules from the plating films into distant areas, in the second period T2 and the third period T3, change according to respective areas (i.e., the sizes of the opening 302a and/or the arrangement density of the openings 302a). Thus, in the case that stirring of the plating liquid Q by the paddle 235 is performed all the time (including the second and third periods), diffusing of the accelerator molecules is uniformized as a result of stirring, and the density difference of the accelerator molecules, that are to be re-adsorbed, according to respective areas is lowered. Thus, for further improving uniformity of the height of plural bumps, it is preferable that stirring of the plating liquid Q by the paddle 235 be stopped or the strength of stirring be weakened, during the third period T3 or during both the second period T2 and the third period T3.

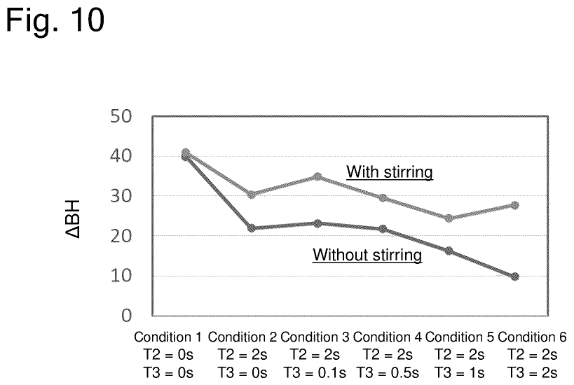

FIG. 10 is a graph which shows comparison between the degrees of bump height dispersion ΔBHs in the cases that stirring of the plating liquid Q by the paddle 235 is stopped and is not stopped in the third period T3. As can be understood from the graph, stopping of stirring of the plating liquid Q provides great effect for lowering the degrees of bump height dispersion ΔBHs.

Further, as explained above, by making desorption and re-adsorption of the accelerator molecules occur, distribution of the plating rates after re-adsorption becomes that opposite to that before desorption; and, for uniformizing the film thickness of the plating films (the bumps 303), it is effective if the length of the plating time, during that the above plating rates after re-adsorption are maintained, is extended sufficiently long. Thus, it is preferable that the operation for supplying a reverse-current pulse and stopping electric current thereafter be performed in a first half period of the whole period of the plating process, for example.

In the above-explained embodiment shown in FIG. 4, operation for supplying a reverse-current pulse and stopping electric current is performed only once in the middle of the first period T1; however, it may be possible to perform the above operation plural times. As explained above, the degrees of density of the accelerator molecules re-adsorbed to the areas in the surface of the plating film are different from one another according to the areas (the stage (D) in FIG. 9); however, after the third period T3, specifically, after a length of time has elapsed since resuming of operation for supplying the positive-direction electric current, the number of accelerator molecules, which are to be re-adsorbed, increases gradually, and the state of the density of the accelerator molecules existing on the surface of the plating film gradually approaches a saturation state, and, as a result, the degrees of density of the accelerator molecules become uniform irrespective of the areas. Thus, by performing, plural times, operation for supplying a reverse-current pulse and stopping electric current, it becomes possible to repeat the process comprising desorption and re-adsorption of accelerator molecules, and, accordingly, it becomes possible to produce density difference of accelerator molecules every time when re-adsorption occurs. As a result, it becomes possible to make the film thickness of the plating film (i.e., the bumps 303) more uniform.

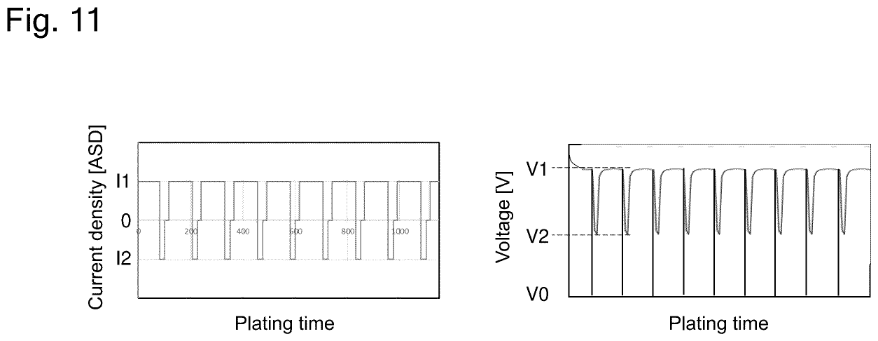

FIG. 11 is a graph which shows time waveforms of plating electric current and a corresponding voltage outputted from the electric power source 270, in an embodiment in which operation for supplying a reverse-current pulse and stopping electric current is performed plural times. In the embodiment shown in each of FIG. 4 and FIG. 9, the electric power source 270 is controlled by the controller 260 for outputting electric power having set (for example, constant) current values I1 and I2. Thus, as shown in FIG. 11, rise time is required for making the output voltage of the electric power source 270 return to the voltage V1, that corresponds to the positive-direction electric current I1, after applying of a reverse-current pulse and stopping of electric current. Temporal change of the output voltage such as that explained above occurs due to the matter that, when the state of adsorption of the additives (an accelerator and an inhibitor) on the surface of the plating film changes, the electric resistance (polarization resistance) on the surface of the cathode, i.e., the surface of the plating film, changes.

Specifically, as shown in FIG. 11, the output voltage changes from V1 to V0 as a result of application of a reverse-current pulse, and, thereafter, temporarily returns to V1 right after application of the positive-direction electric current I1 (in this regard, since this voltage change occurs in a very short period of time in the time scale in FIG. 11, the change is depicted by narrow vertical lines in the figure). The state at that point in time, i.e., the point in time right after application of the positive-direction electric current I1, is that the quantity of accelerators adsorbed to the surface of the plating film is very few, and, from the state, adsorption of the accelerators progresses gradually. Thus, the resistance becomes small gradually, and, accordingly, the output voltage becomes small and approaches V2. Thereafter, in addition to adsorbing of accelerators, adsorbing of inhibitors starts, and effect to suppress forming of the plating film due to the inhibitors becomes strong. Thereafter, the output voltage changes its state from a decreasing state to an increasing state, and gradually becomes large and approaches V1, wherein the extreme value in the decreasing state is V2. Adsorption/concentration of the accelerators is continued during the above process, and, finally, effect due to the accelerator and effect due to the inhibitors are balanced to enter an equilibrium state thereof, and the output voltage is stabilized at V1. That is, the quantity of the accelerators accumulated on the surface of the plating film reaches a saturation point when the quantity reaches a certain quantity.

In this regard, the matter that the quantity of the accumulated accelerators reaches a saturation point means that the respective degrees of density of the accelerator molecules existing on respective areas in the surface of the plating film become uniform irrespective of the respective areas; thus, it will be understood from the explanation relating to above-explained FIG. 9 that, if desorption of the accelerators is performed in the state that a saturation state such as that explained above or a state close thereto has been achieved, the difference in density according to areas, that is produced thereafter, i.e., that is produced when re-adsorption of the accelerator molecules has occurred, becomes the largest. Thus, in the case that plural reverse-current pulses are applied in a manner similar to that in the embodiment in FIG. 11, it is preferable that a next reverse-current pulse be applied after the value of the output voltage V of the electric power source 270 has returned to a value sufficiently close to that of the original voltage V1 (for example, 90 percent of the original voltage V1).

In the above description, embodiments of the present invention have been explained based on some examples; and, in this regard, the above explained embodiments of the present invention are those used for facilitating understanding of the present invention, and are not those used for limiting the present invention. It is obvious that the present invention can be changed or modified without departing from the scope of the gist thereof, and that the present invention includes equivalents thereof. Further, it is possible to arbitrarily combine components or omit a component(s) disclosed in the claims and the specification, within the scope that at least part of the above-stated problems can be solved or within the scope that at least part of advantageous effect can be obtained.

1. A plating apparatus for forming bumps on a substrate comprising:
a substrate holder constructed to hold the substrate;
a plating tank constructed to store plating liquid and the substrate holder;
an anode arranged in the inside of the plating tank in such a manner that the anode faces the substrate held by the substrate holder;
an electric power source constructed to supply electric current flowing between the substrate and the anode; and
a controller;
wherein
the controller is constructed to make the electric power source output electric current that comprises a first period during that positive-direction electric current is supplied for depositing metal on the substrate from the plating liquid, a second period during that at lest one reverse-current pulse, that flows in a direction opposite to a direction of the positive-direction electric current, is supplied, and a third period during that supplying of electric current is stopped, wherein the third period is a period in the middle of a transition from the reverse-current pulse to the positive-direction electric current.

2. The plating apparatus as recited in claim 1 further comprising
a paddle for stirring the plating liquid in the plating tank; wherein
the controller is constructed to weaken the strength of or stop the stirring performed by the paddle during at least the third period.

3. The plating apparatus as recited in claim 2, wherein the controller is constructed to weaken the strength of or stop the stirring performed by the paddle during the second period and the third period.

4. The plating apparatus as recited in Claim 1, wherein the controller is constructed to make the electric power source output current that comprises plural pairs of the second periods and the third periods.

5. The plating apparatus as recited in claim 4, wherein the controller is constructed to make the reverse-current pulse be supplied, after the output voltage of the electric power source in the first period becomes that equal to or greater than 90 percent of a stable output voltage of the electric power source during the first period.

6. The plating apparatus as recited in claim 1, wherein the substrate comprises a metal seed layer and a shielding film for shielding, from the plating liquid, the metal seed layer except for areas in the metal seed layer where bumps are to be formed.

7. The plating apparatus as recited in claim 6, wherein the shielding film has a pattern corresponding to plural bumps having different diameters.

8. The plating apparatus as recited in claim 6, wherein the shielding film has a pattern that makes plural bumps, that are to be formed, be arranged in areas in such a manner that different areas have different degrees of density of the bumps.

9. A method for forming bumps on a substrate comprising:
supplying, between the substrate and an anode arranged in a plating tank, electric current that comprises a first period during that positive-direction electric current is supplied for depositing metal on the substrate from a plating liquid in the plating tank, a second period during that at least one reverse-current pulse, that flows in a direction opposite to a direction of the positive-direction electric current, is supplied, and a third period during that supplying of electric current is stopped, wherein the third period is a period in the middle of a transition from the reverse-current pulse to the positive-direction electric current.

10. The plating method as recited in claim 9 further comprising: in the first period, stirring the plating liquid with first strength; and, at least in the second period in the second period and the third period, stirring the plating liquid with second strength that is weaker than the first strength, or stopping the stirring.
